(19) United States
(12) Patent Application Publication
(10) Pub. No.: US 2026/0361276 A1
(43) Pub. Date: Nov. 12, 2026

(54) DIGITAL PREDISTORTION FOR DRIVER AMPLIFIER IN TRANSMITTER SYSTEM BASED ON FEEDBACK FROM RF FRONT END

(71) Applicant: QUALCOMM Incorporated, San Diego, CA (US)

(72) Inventors: Kaushik GHOSAL, Hyderabad (IN); Ashish Kumar BONDIA, Hyderabad (IN); Tarandeep VIRK, San Diego, CA (US); Devanshu Singh SINGH GAHARWAR, Indore (IN); Sangeeta BIND, Vadodara (IN)

(21) Appl. No.: 19/204,202

(22) Filed: May 9, 2025

(51) Int. Cl. H03F 1/32; H03F 3/24

(52) U.S. Cl. CPC H03F 1/3276; H03F 3/24; H03F 2203/21193

(57) ABSTRACT

A transmitter system, including: a radio frequency front end (RFFE), comprising: a power amplifier (PA); and a coupler coupled to an output of the PA; a transmitter, comprising: a driver amplifier (DA) configured to amplify a first radio frequency (RF) signal to generate a second RF signal; and a digital predistortion (DPD) circuit configured to predistort a first baseband signal to generate a second baseband signal, wherein the first RF signal is based on the second baseband signal, and wherein the DPD circuit is configured to predistort the first baseband signal based on a nonlinearity characteristic of the DA based at least in part on a feedback RF signal received from the coupler of the RFFE.

### FIELD

This disclosure relates generally to digital predistortion (DPD), and in particular, to applying DPD to a driver amplifier (DA) based on feedback from a radio frequency front end (RFFE).

### BACKGROUND

A transmitter system may include a set of amplification stages to generate a transmit radio frequency (RF) signal for wireless transmission via an antenna. In many instances, a power amplifier (PA), serving as the last amplification stage, may be operated in a nonlinear manner (e.g., to have a nonlinear amplitude transfer function) to achieve a high output power for the transmit RF signal while operating the PA in a power efficient manner. In other modes of operation (e.g., to achieve lower power consumption for the transmitter system), the PA may be bypassed or operated in a more linear manner, in such cases, a pre-amplifier or driver amplifier (DA) may be operated to generate or contribute more significantly to the generation of the transmit RF signal.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a transmitter system. The transmitter system includes: a radio frequency front end (RFFE), comprising: a power amplifier (PA); and a coupler coupled to an output of the PA; a transmitter, comprising: a driver amplifier (DA) configured to amplify a first radio frequency (RF) signal to generate a second RF signal; and a digital predistortion (DPD) circuit configured to predistort a first baseband signal to generate a second baseband signal, wherein the first RF signal is based on the second baseband signal, and wherein the DPD circuit is configured to predistort the first baseband signal based on a nonlinearity characteristic of the DA as indicated by a feedback RF signal received from the coupler of the RFFE.

Another aspect of the disclosure relates to a method of generating a transmit radio frequency (RF) signal in a transmitter system. The method includes: amplifying a first radio frequency (RF) signal to generate a second RF signal in accordance with a nonlinear transfer function at a transmitter; receiving a feedback RF signal from an RF front end (RFFE) at the transmitter, wherein the feedback RF signal is based on the transmit RF signal; and predistorting a baseband signal based on the feedback RF signal to achieve a substantially linear amplitude relationship between the transmit RF signal and the baseband signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a block diagram of an example transmitter system in accordance with an aspect of the disclosure.

FIG. 1B illustrates graphs of example transfer functions associated with the transmitter system of FIG. 1A in accordance with another aspect of the disclosure.

FIG. 2A illustrates a block diagram of another example transmitter system in accordance with another aspect of the disclosure.

FIG. 2B illustrates graphs of example transfer functions associated with the transmitter system of FIG. 2A in accordance with another aspect of the disclosure.

FIG. 3 illustrates a block diagram of another example transmitter system in accordance with another aspect of the disclosure.

FIG. 4 illustrates a block diagram of another example transmitter system in accordance with another aspect of the disclosure.

FIG. 5 illustrates a block diagram of another example transmitter system in accordance with another aspect of the disclosure.

FIG. 6 illustrates a block diagram of another example transmitter system in accordance with another aspect of the disclosure.

FIG. 7 illustrates a block diagram of an example transceiver system in accordance with another aspect of the disclosure.

FIG. 8 illustrates a block diagram of an example wireless communication system in accordance with another aspect of the disclosure.

FIG. 9 illustrates an example method of generating a transmit radio frequency (RF) signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

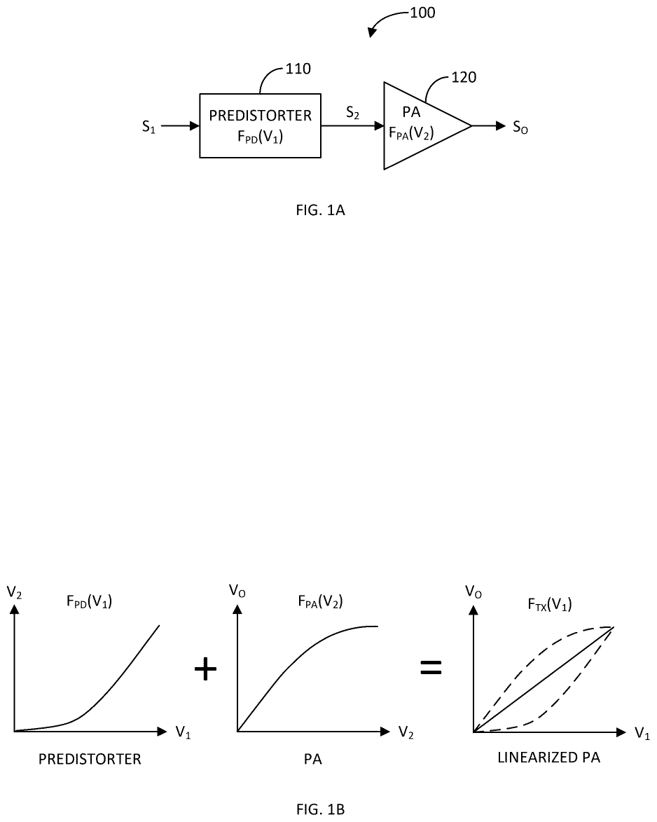

FIG. 1A illustrates a block diagram of an example transmitter system 100 in accordance with an aspect of the disclosure. The transmitter system 100 includes a predistorter 110 and a power amplifier (PA) 120. The predistorter 100 is configured to apply a predistortion of a first signal S₁ with an amplitude V₁ to generate a second signal S₂ with an amplitude of V₂ based on an amplitude transfer function F_{PD}(V₁) (e.g., V₂=F_{PD}(V₁)). As discussed further herein, the predistortion applied to the first signal S₁ is for linearizing the overall amplitude transfer function of the transmitter system 100.

The PA 120 is configured to amplify the second signal S₂ to generate an output signal S_{O} with an amplitude V_{O} based on an amplitude transfer function F_{PA}(V₂) (e.g., V_{O}=F_{PA}(V₂)). The PA transfer function F_{PA}(V₂) may exhibit a non-linear response due to compression. With the predistortion applied to the first signal S₁, the amplitude transfer function F_{TX}(V₁) (e.g., V_{O}=F_{TX}(V₁)) of the transmitter system 100 may be substantially linear. The aforementioned linearization of the transfer function F_{TX}(V₁) of the transmitter system 100 is discussed further herein with reference to FIG. 1B.

FIG. 1B illustrates graphs of example amplitude transfer functions associated with the transmitter system 100 in accordance with another aspect of the disclosure. The first graph on the left depicts the amplitude transfer function F_{PD}(V₁) of the predistorter 110. The vertical axis of the first graph represents the amplitude V₂ of the second signal S₂ and the horizontal axis represents the amplitude V₁ of the first signal S₁. The second graph in the middle depicts the amplitude transfer function F_{PA}(V₂) of the PA 120. The vertical axis of the second graph represents the amplitude V_{O} of the output signal V_{O} and the horizontal axis represents the amplitude V₂ of the second voltage signal S₂. The third graph on the right depicts the amplitude transfer function F_{TX}(V₁) of the transmitter system 100. The vertical axis of the third graph represents the amplitude V_{O} of the output signal S_{O} and the horizontal axis represents the amplitude V₁ of the first signal S₁.

As depicted in the second (middle) graph, the transfer function F_{PA}(V₂) of the PA 120 has a non-linear response due to compression when the amplitude V₂ of the input signal S₂ to the PA 120 becomes large. The transfer function F_{PD}(V₁) of the predistorter 110 (or the predistortion applied to the input signal S₁) is inverse (expansive) with respect to the transfer function F_{PA}(V₂) of the PA 120 such that the product of their transfer functions F_{PD}(V₁)*F_{PA}(V₂) produces a transfer function F_{TX}(V₁) for the transmitter system 100 that is substantially linear, as illustrated as a solid line in the third graph. The third graph also shows the transfer functions F_{PD}(V₁) and F_{PA}(V₂) of the predistorter 110 and PA 120 as dashed lines for illustrative purpose.

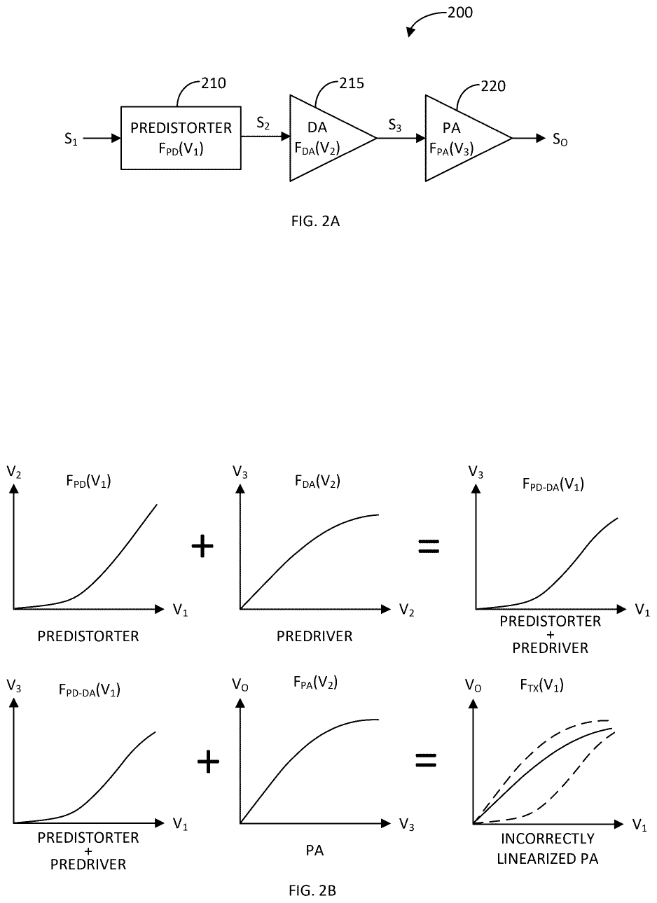

FIG. 2A illustrates a block diagram of another example transmitter system 200 in accordance with another aspect of the disclosure. The transmitter system 200 is similar to transmitter system 100 but further includes a driver amplifier (DA) 215 situated between a predistorter 210 and a power amplifier (PA) 220. In particular, the predistorter 210 is configured to apply a predistortion to a first signal S₁ with an amplitude V₁ to generate a second signal S₂ with an amplitude V₂ based on an amplitude transfer function F_{PD}(V₁) (e.g., V₂=F_{PA}(V₁)). The DA 215 is configured to amplify the second signal S₂ to generate a third signal S₃ with an amplitude V₃ based on an amplitude transfer function F_{DA}(V₂) (e.g., V₃=F_{PA}(V₂)). The PA 220 is configured to amplify the third signal S₃ to generate an output signal S_{O} with an amplitude V_{O} based on an amplitude transfer function F_{PA}(V₃) (e.g., V_{O}=F_{PA}(V₃)).

In this example, the transfer function F_{PD}(V₁) of the predistorter 210 is configured to be the inverse (expansive) of the transfer function F_{PA}(V₃) (compressive) of the PA 220. As discussed with reference to the transmitter system 100, the transfer function F_{PD}(V₁) of the predistorter 210 being the inverse of the transfer function F_{PA}(V₃) linearizes the transfer function F_{TX}(V₁) of the transmitter system 200 if the transfer function F_{DA}(V₂) of the DA 215 is linear. However, if the transfer function F_{DA}(V₂) of the DA 215 is non-linear (e.g., due to compression), the transfer function F_{TX}(V₁) of the transmitter system 200 may no longer be linear. This is further explained with reference to FIG. 2B.

FIG. 2B illustrates graphs of example transfer functions associated with the transmitter system 200 in accordance with another aspect of the disclosure. The first graph at the top-left depicts the transfer function F_{PD}(V₁) of the predistorter 210. The vertical axis of the first graph represents the amplitude V₂ of the second signal S₂ and the horizontal axis represents the amplitude V₁ of the first signal S₁. The second graph at the top-middle depicts the transfer function F_{DA}(V₂) of the DA 215. The vertical axis of the second graph represents the amplitude V₃ of the third signal S₃ and the horizontal axis represents the amplitude V₂ of the second signal S₂.

The third graph at the top-right (and reproduced at the bottom-left) depicts the combined transfer function F_{PD-DA}(V₁) of the predistorter 210 and the DA 215. The vertical axis of the third graph represents the amplitude V₃ of the third signal S₃ and the horizontal axis represents the amplitude V₁ of the first signal S₁. The fourth graph at the bottom-middle depicts the transfer function F_{PA}(V₃) of the PA 220. The vertical axis of the fourth graph represents the amplitude V_{O} of the output signal S_{O} and the horizontal axis represents the amplitude V₃ of the third signal S₃. The fifth graph at the bottom-right depicts the transfer function F_{TX}(V₁) of the transmitter system 200. The vertical axis of the third graph represents the amplitude V_{O} of the output signal S_{O} and the horizontal axis represents the amplitude V₁ of the first signal S₁.

As depicted in the bottom-middle graph, the transfer function F_{PA}(V₃) of the PA 220 has a non-linear response due to compression when the amplitude V₃ of the input signal S₃ to the PA 220 becomes large. The transfer function F_{PD}(V₁) of the predistorter 210 (or the predistortion applied to the input signal S₁) is inverse (expansive) with respect to the transfer function F_{PA}(V₃) of the PA 220 such that the product of their transfer functions F_{PD}(V₁)*F_{PA}(V₃) would produce a linear transfer function F_{TX}(V₁) for the transmitter system 200 if the transfer function F_{DA}(V₂) of the DA 215 were linear.

However, as depicted in the top-middle graph, the DA 215 has a non-linear transfer function F_{DA}(V₂) due to compression. Accordingly, as depicted in the combined transfer function F_{PD-DA}(V₁) of the predistorter 210 and the DA 215 at the top-right (as well as bottom-left), the combined transfer function F_{PD-DA}(V₁) is no longer inverse to the transfer function F_{PA}(V₃) of the PA 220. As a result, the transfer function F_{TX}(V₁) of the transmitter system 200 is no longer linear, exhibiting some degree of nonlinearity. Thus, to achieve a linear transfer function F_{TX}(V₁) for the transmitter system 200, either maintain the DA 215 operating linearly based on the operating (dynamic) range of the amplitude V₂ of its input signal S₂ operating or applying predistortion to correct for the non-linearity of the DA 215.

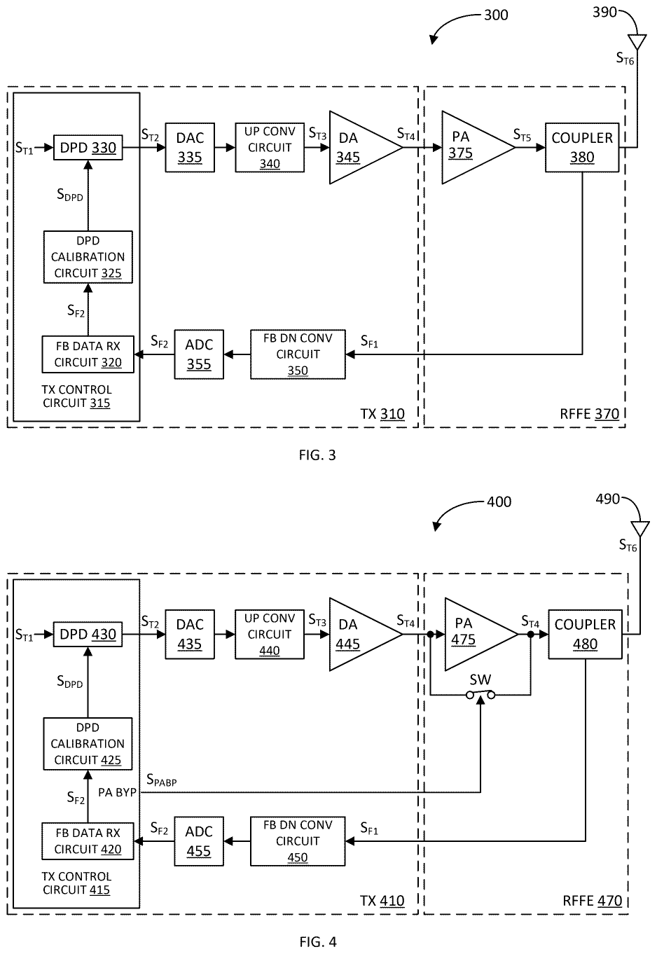

FIG. 3 illustrates a block diagram of another example transmitter system 300 in accordance with another aspect of the disclosure. The transmitter system 300 includes a transmitter (TX) 310, a radio frequency front end (RFFE) 370, and an antenna 390. The transmitter 310 and RFFE 370 may be implemented in separate circuit entities (e.g., separate ICs, an IC and a separate dedicated circuit, or two separated dedicated circuits on different printed circuit boards (PCBs)).

The transmitter 310 includes a transmitter (Tx) control circuit 315 including a feedback (FB) data receive (RX) circuit 320, a digital predistortion (DPD) calibration circuit 325, and a DPD 330. The transmitter 310 further includes a digital-to-analog converter (DAC) 335, a frequency upconverting circuit 340, a driver amplifier (DA) 345, a feedback frequency downconverting circuit 350, and an analog-to-digital converter (ADC) 355. The RFFE 370 includes a power amplifier (PA) 375 and a coupler 380. The transmitter system 300 may include other components including baseband filters, receive paths, other transmit and receive chains, but are not shown for purpose of simplicity.

The DPD 330 is configured to predistort an input transmit baseband signal S_{T1} to generate a predistorted transmit baseband signal S_{T2}. The predistortion of the baseband transmit signal S_{T1} may be for compensating for nonlinearity of the PA 375 to achieve a substantially linear transfer function between an amplitude of a radio frequency (RF) signal S_{T5} generated by the PA 375 and an amplitude of the input transmit baseband signal S_{T1}. The DAC 335 is configured to convert the predistorted transmit baseband signal S_{T2} into an analog signal and the frequency upconverting circuit 340 is configured to frequency upconvert the analog signal to generate a transmit RF signal S_{T3}. The DA 345 is configured to pre-amplify the transmit RF signal S_{T3} to generate a pre-amplified transmit RF signal S_{T4}.

The transmitter 310 provides the pre-amplified transmit RF signal S_{T4} to the RFFE 370, and specifically, to an input of the PA 375. The PA 375 is configured to power amplify the pre-amplified RF signal S_{T4} to generate an amplified transmit RF signal S_{T5}. The coupler 380 is configured to: (1) passthrough a first (e.g., larger) portion of the amplified transmit RF S_{T5} as a transmit RF signal S_{T6} to the antenna 390 for wireless transmission, and (2) generate a second (e.g., smaller) portion of the amplified transmit RF S_{T5} as a feedback RF signal S_{F1} for DPD (and/or other) purposes.

The RFFE 370 provides the feedback RF signal S_{F1} to the transmitter 310, and specifically, to an input of the feedback frequency downconverting circuit 350. The feedback frequency downconverting circuit 350 is configured to frequency downconvert the feedback RF signal S_{F1} and the ADC 355 is configured to convert the frequency downconverted signal into a feedback digital signal S_{F2}. The FB data receive circuit 320, serving as a digital interface, is configured to receive and provide the feedback digital signal S_{F2} to the DPD calibration circuit 325. In accordance with a DPD calibration procedure, the DPD calibration circuit 325 models the non-linearity of the PA 375 based on the feedback digital signal S_{F2} to generate a DPD calibration signal S_{DPD} to calibrate the DPD 330 so as to predistort the input digital baseband signal S_{T1} to achieve a substantially linear transfer function for the transmitter system 300 (e.g., to compensate for the nonlinearity of the PA 375).

As the discussed with reference to the transmitter system 200, for the DPD calibration circuit 325 to accurately characterize the nonlinearity of the PA 375 for the purpose of generating the DPD calibration signal S_{DPD}, the DA 345 should be substantially linear because otherwise the characterization of the nonlinearity of the PA 375 may be in error. As a consequence, the capable output power of the DA 345 may be backed off so that it operates in the linear region; and/or the supply voltage/bias of the DA 345 may be set relatively high so that the DA 345 operates in the linear region. And, as a further consequence, the output power of the transmit RF signal S_{T6} of the transmitter system 300 may be lower and/or the power consumption of the transmitter system 300 may be higher due to operating the DA 345 in the linear region.

FIG. 4 illustrates a block diagram of another example transmitter system 400 in accordance with another aspect of the disclosure. The transmitter system 400 is similar to transmitter system 300, and includes many of the same/similar elements as indicated by the same reference numbers with the exception that their most significant digit is a “4” in transmitter system 400 instead of a “3” as in transmitter system 300.

The transmitter system 400 differs from transmitter system 300 in that the RFFE 470 includes a PA bypass switch SW, which is controlled by a PA bypass signal S_{PABP} generated by the transmitter control circuit 415. In certain modes, the DPD calibration circuit 425 may be configured to characterize the nonlinearity of the DA 445 based on the feedback digital signal S_{F2}, and generate the DPD calibration circuit S_{DPD} based on the characterization of the nonlinearity of the DA 445. Accordingly, the DPD 430 is configured to predistort the input digital baseband signal S_{T1} to achieve a substantially linear transfer function for the transmitter system 400 (e.g., the amplitude of the RF signal S_{T4} generated by the DA 445 varies substantially linear with variation in the amplitude of the input digital baseband signal S_{T1}). It shall be understood that the transmit control circuit 415 may perform DPD for either the PA 475 or the DA 445 based on different modes of operation (e.g., where in a certain mode, the DPD 330 performs digital predistortion to compensate for the nonlinearity of the DA 345, and the mode may be switched where the DPD 330 performs digital predistortion to compensate for the nonlinearity of the PA 475.

Note that elements of the RFFE 470 are utilized to characterize and compensate for the nonlinearity of the DA 445. That is, for characterizing the nonlinearity of the DA 445, the transmitter control circuit 415 asserts the PA bypass signal S_{PABP} to close the PA bypass switch SW so that the feedback RF signal S_{F1} is based on the nonlinearity of the DA 445 and not the nonlinearity of the PA 475. Accordingly, the coupler 480 generates the feedback RF signal S_{F1} being a sampled portion of the RF signal S_{T4} generated by the DA 445 for characterizing the nonlinearity of the DA 445. That is, the DPD calibration circuit 425 may be based at least in part of a pre-characterization data about the DA 445 that may be augmented or adjusted by the feedback loop. Accordingly, the DA 445 may be modeled beforehand to identify the non-linear response and then the feedback loop augments the modeling.

Thus, in certain transmit mode (e.g., PA bypass mode) where the PA 475 is disabled and placed in a low power mode for power saving purposes, and the PA bypass switch SW is closed so that the DA 445 generates the final transmit RF signal S_{T6} provided to the antenna 490 for wireless transmission, the DA 445 may be operated in a nonlinear region so as to increase the output power of the final transmit RF signal S_{T6}. To compensate for the nonlinearity of the DA 445, the DA DPD calibration circuit 425 characterizes the nonlinearity of the DA 445 based on the feedback RF signal S_{F1} (via the downconverted and digitized feedback signal S_{F2} received by the FB data Rx circuit 420) received from the coupler 480 of the RFFE 470 to generate the DPD calibration signal S_{DPD}. And, the DPD 430 predistorts the input transmit baseband signal S_{T1} based on the DPD calibration signal S_{DPD} to achieve a substantially linear transfer function for the transmitter system 400.

The transmitter system 400 provides improved overall chain or overall chain linearity by employing DPD for both the DA 445 and the PA 475. Further, the transmitter system 400 allows for higher transmit power levels with the PA 475 bypassed while maintaining linearity (e.g., to allow the PA 475 to be bypassed while having the capability of increasing the output power of the DA 445 and applying DPD for the DA 445 to maintain transmit chain linearity).

FIG. 5 illustrates a block diagram of another example transmitter system 500 in accordance with another aspect of the disclosure. The transmitter system 500 is similar to transmitter system 300, and includes many of the same/similar elements as indicated by the same reference numbers with the exception that their most significant digit is a “5” in transmitter system 500 instead of a “3” as in transmitter system 300.

The transmitter system 500 differs from transmitter system 300 in that the RFFE 570 includes a signal tracking (ST) (e.g., average power tracking (APT), envelope tracking (ET), etc.) voltage regulator (VR) 585 configured to generate a PA supply voltage V_{PA} based on a signal tracking (ST) control signal S_{PAST}. The transmitter (TX) 510 is configured to generate and provide the ST control signal S_{PAST} to the RFFE 570; and more specifically, the transmitter control circuit 515 is configured to generate and provide the ST control signal S_{PAST} to the ST voltage regulator 585.

In certain modes (e.g., maximum power reduction (MPR) mode), the PA 575 may be operated in the linear region by way of the PA signal tracking control signal S_{PAST}. For example, the transmitter control circuit 515 may generate the ST control signal S_{PAST} to control the ST voltage regulator 585 to generate/adjust the PA supply voltage V_{PA} so as to maintain the PA 575 exclusively in the linear region based on the operating range of the power or envelope level of the RF signal S_{T4} or S_{T5} at the input or output of the PA 575, respectively.

As the PA 575 is being operated in the linear region in this mode, the transmitter 510 may use the resources of the RFFE 570 to calibrate the DPD 530 to achieve a substantially linear transfer function for the transmitter system 500 (e.g., where the amplitude of the transmit RF signal S_{T6} varies linearly with the amplitude of the input digital baseband signal S_{T1}). That is, because the PA 575 is operated linearly, the PA 575 does not affect the nonlinear characteristic of the DA 545 as reflected in the feedback RF signal S_{F1}.

Thus, in this mode, the DA 545 may be operated in a nonlinear manner to increase the power of the final transmit RF signal S_{T6}, while the DPD 530 predistorts the input digital transmit signal S_{T1} to achieve a substantially linear transfer function for the transmitter system 500. In this regard, the DA DPD calibration circuit 525 characterizes the nonlinearity of the DA 545 based on the feedback RF signal S_{F1} (via the downconverted and digitized feedback signal S_{F2} received by the FB data Rx circuit 520) received from the coupler 580 of the RFFE 570 to generate the DPD calibration signal S_{DPD}. The DPD 530 predistorts the input transmit baseband signal S_{T1} based on DPD calibration signal S_{DPD}.

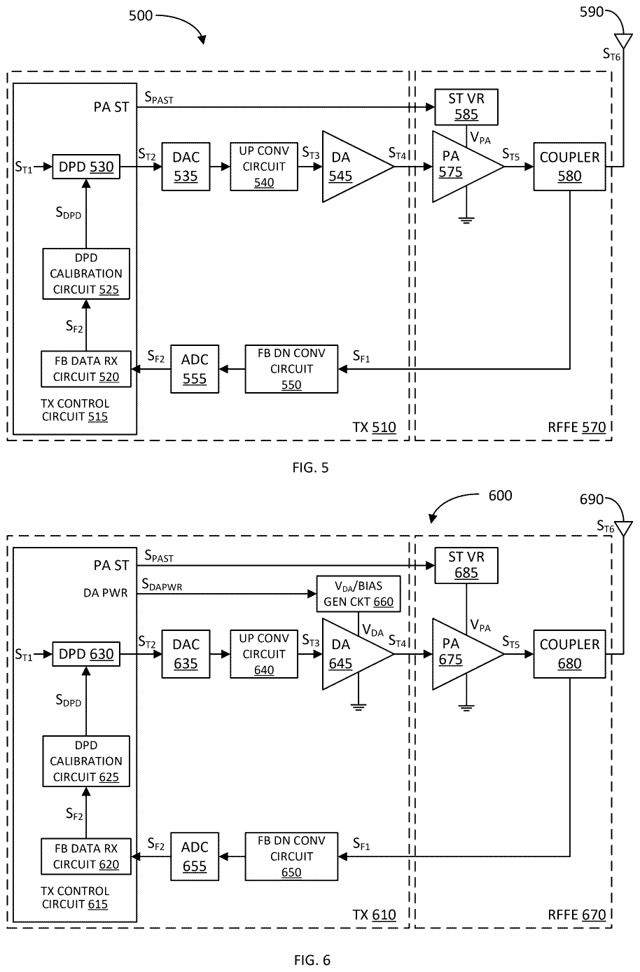

FIG. 6 illustrates a block diagram of another example transmitter system 600 in accordance with another aspect of the disclosure. The transmitter system 600 is similar to transmitter system 500, and includes many of the same/similar elements as indicated by the same reference numbers with the exception that their most significant digit is a “6” in transmitter system 600 instead of a “5” as in transmitter system 500.

The transmitter system 600 differs from transmitter system 500 in that the transmitter (TX) 610 further includes a driver amplifier (DA) supply voltage V_{DA}/bias generating circuit 660 configured to generate a supply/bias voltage V_{DA} for the DA 645 based on DA power control signal S_{DAPWR}. The transmitter control circuit 615 is configured to generate the DA power control signal S_{DPWR}.

In certain modes (e.g., PA APT, ET, and/or other modes), the PA 675 may be operated in the linear region by way of the PA signal tracking control signal S_{PAST}, as discussed with reference to transmitter system 500. As the PA 675 is operated in the linear region in this mode, the transmitter 610 may use the resources of the RFFE 670 to calibrate the DPD 630 to achieve a substantially linear transfer function for the transmitter system 600 (e.g., where the amplitude of the final transmit RF signal S_{T6} varies linearly with the amplitude of the input digital baseband signal S_{T1}).

Thus, in certain modes, the DA 645 may be operated with a lower supply voltage/bias V_{DA} to save power for the transmitter system 600. Because of the lower supply voltage/bias V_{DA}, the DA 645 operates in its nonlinear region. In this regard, the DA DPD calibration circuit 625 characterizes the nonlinearity of the DA 645 based on the feedback RF signal S_{F1} (via the downconverted and digitized feedback signal S_{F2} received by the FB data Rx circuit 620) received from the coupler 680 of the RFFE 670 to generate the DPD calibration signal S_{DPD}. The DPD 630 predistorts the input transmit baseband signal S_{T1} based on DPD calibration signal S_{DPD}.

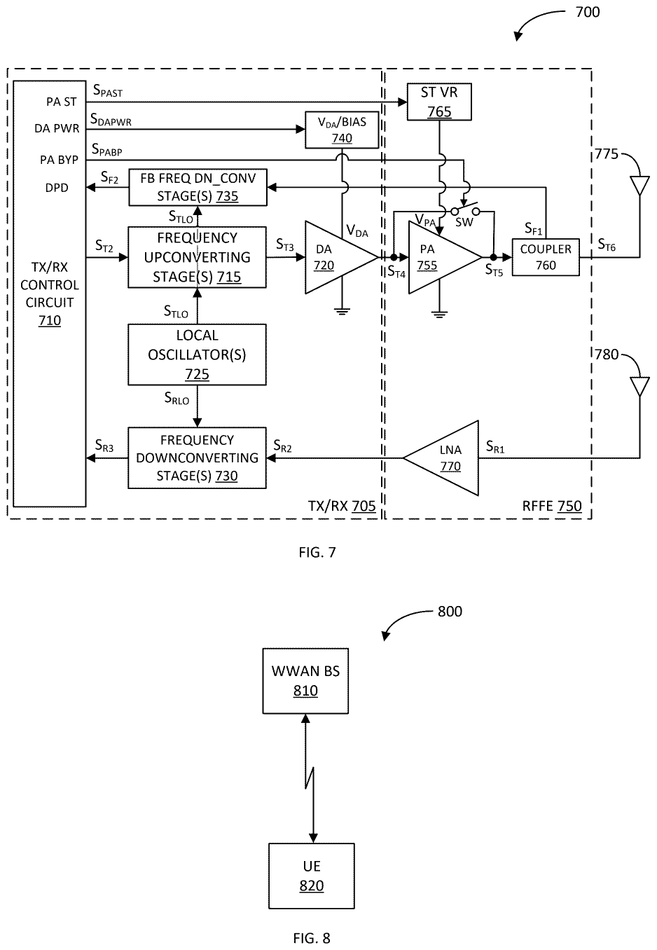

FIG. 7 illustrates a block/schematic diagram of an example transceiver 700 in accordance with another aspect of the disclosure. The transceiver 700 includes the various features of the transmitter systems 400, 500, and 600 previously discussed, as well as a receiver. The transceiver 700 includes a transceiver (TX/RX) 705, a radio frequency front end (RFFE) 750, a transmit antenna 775, and a receive antenna 780. The transceiver 705 and RFFE 750 may be implemented in separate circuit entities (e.g., separate ICs, an IC and a separate dedicated circuit, or two separated dedicated circuits on different printed circuit boards (PCBs)). It shall be understood that the transceiver 700 may instead include a single antenna common to both the receiver and transmitter portions of the transceiver 700.

From both transmitter and receiver perspectives, the transceiver 705 includes a transceiver (Tx/Rx) control circuit 710 and one or more local oscillators (LO) 725.

From a transmitter perspective, the transceiver 705 includes one or more frequency upconverting stages 715, a driver amplifier (DA) 720, and a V_{DA}/bias generating circuit 740. The one or more frequency upconverting stages 715 is configured to frequency upconvert a baseband signal S_{T2} received from the transceiver control circuit 710 using one or more transmit LO signals S_{TLO} generated by the LO 725 to generate a transmit RF signal S_{T3}. The DA 720 is configured to amplify the transmit RF signal S_{T3} to generate an amplified transmit RF signal S_{T4}.

From a transmitter perspective, the RFFE 750 includes a power amplifier (PA) 755, a coupler 760, and a signal tracking voltage regulator (ST VR) 765. If the PA 755 is not bypassed, the PA 755 is configured to power amplify the transmit RF signal S_{T4} from the DA 720 of the transceiver 705 to generate a power amplified transmit RF signal S_{T5}. If the PA 755 is bypassed, the transmit RF signal S_{T4} from the DA 720 of the transceiver 705 is provided to an input of the coupler 760. From the transmit RF signal S_{T4} or S_{T5}, the coupler 760 provides a final transmit RF signal S_{T6} to the antenna 775 for wireless transmission, and a feedback RF signal S_{F1} for DPD (and/or other) purposes as previously discussed. The ST voltage regulator 765 generates a supply voltage V_{PA} for the PA 755 based on a signal tracking (ST) control signal S_{PAST} received from the transceiver 705.

From a receiver perspective, the transceiver 705 includes one or more frequency downconverting stages 730, and the RFFE 750 includes a low noise amplifier (LNA) 770. The LNA 770 is configured to receive a received RF signal S_{R1} wirelessly picked up by the received antenna 780. The LNA 770 is configured to amplify the received RF signal S_{R1} to generate an amplified received RF signal S_{R2}. The one or more frequency downconverting stages 730 is configured to frequency downconvert the received RF signal S_{R2} using one or more received LO signals S_{RLO} generated by the LO 725 to generate a received baseband signal S_{R3}. The received RF signal S_{R3} is provided to the transceiver control circuit 710 for further processing (e.g., by a modem component to recover data/information therein).

From a transmitter perspective, the transceiver 700 may operate per any of the different modes described with reference to transmitter systems 400, 500, and 600. That is, in PA bypass mode (e.g., transmitter system 600): the transceiver control circuit 710 may: (1) assert the PA bypass signal S_{PABP} to close the PA bypass switch SW and bypass the PA 755; (2) operate the DA 720 in its nonlinear region; and (3) generate a predistorted baseband signal S_{T2} to compensate for the nonlinearity of the DA 720 based on a feedback RF signal S_{F1} received from the RFFE 750 (via the feedback signal S_{F2} frequency downconverted by feedback frequency down converting stage(s) 735 using the one or more transmit LO signals S_{TLO}).

In MPR APT mode (e.g., transmitter system 700), the transceiver control circuit 710 may: (1) may generate the S_{PAST} control signal to control the ST voltage regulator 765 to generate the PA supply voltage V_{PA} so as to track the envelope or average power of the transmit RF signal S_{T4} or S_{T5} to operate the PA 755 exclusively in its linear region; 2) operate the DA 720 in its nonlinear region; and (3) generate a predistorted baseband signal S_{T1} to compensate for the nonlinearity of the DA 720 based on a feedback RF signal S_{F1} received from the RFFE 750 (via the feedback signal S_{F2} frequency downconverted by feedback frequency down converting stage(s) 735).

In Low power mode (LPM)/ Mid power mode (MPM) for PA 755 (operating without DPD), the transceiver control circuit 710 may: (1) may generate the S_{PAST} control signal to control the ST voltage regulator 765 to generate the PA supply voltage V_{PA} so as to track the average power of the transmit RF signal S_{T4} or S_{T5} to operate the PA 755 in its linear region; 2) generate the DA power control signal S_{DAPWR} so that the VDA/bias generating circuit 740 lowers the supply voltage V_{DA} of the DA 720 so that it operates in its nonlinear region; and (3) generate a predistorted baseband signal S_{T1} to compensate for the nonlinearity of the DA 720 based on a feedback RF signal S_{F1} received from the RFFE 750 (via the feedback signal S_{F2} frequency downconverted by feedback frequency down converting stage(s) 735).

FIG. 8 illustrates a block diagram of an example wireless communication system 800 in accordance with another aspect of the disclosure. The wireless communication system 800 includes a wireless wideband area network (WWAN) base station (BS) 810 and a user equipment (UE) 820. The WWAN BS 810 and UE 820 may wirelessly communicate with each other in accordance with various protocols, such as New Radio (NR) 5^{th} or 6^{th} Generation (5G) or (6G), or other. Further, although a WWAN is used to exemplify the concepts described herein, it shall be understood that the concepts described herein may be applicable to wireless local area networks (WLANs) (e.g., WiFi), short distance area networks (e.g., Bluetooth), personal area networks, or ultra wideband (UWB) based wireless networks, etc. The UE 820 and/or the WWAN BS 810 may include any one of the aforementioned transmitter system or transceiver.

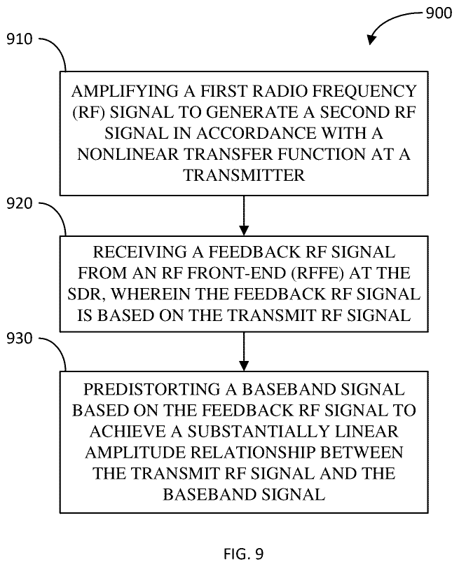

FIG. 9 illustrates an example method 900 of generating a transmit radio frequency (RF) signal in a transmitter system. The method 900 includes: amplifying a first radio frequency (RF) signal to generate a second RF signal in accordance with a nonlinear transfer function at a transmitter (block 910). Examples of means for amplifying a first radio frequency (RF) signal to generate a second RF signal in accordance with a nonlinear transfer function at a transmitter include any of the DAs described herein.

The method 900 further includes receiving a feedback RF signal from an RF front end (RFFE) at the transmitter, wherein the feedback RF signal is based on the transmit RF signal (block 920). Examples of means for receiving a feedback RF signal from an RF front end (RFFE) at the transmitter includes any of the couplers and feedback related circuitry, couplers 480/580/680/780, feedback signal downconverting circuits/stages 450/550/650/735, and ADCs 455/555/655 described herein.

Additionally, the method 900 includes predistorting a baseband signal based on the feedback RF signal to achieve a substantially linear amplitude relationship between the transmit RF signal and the baseband signal (block 930). Examples of means for predistorting a baseband signal based on the feedback RF signal to achieve a substantially linear amplitude relationship between the transmit RF signal and the baseband signal include any of the DPD calibration circuits 425/525/625, DPDs 430/530/630, and transceiver control circuit 710 described herein

The following provides an overview of aspects of the present disclosure:

Aspect 1: A transmitter system, comprising: a radio frequency front end (RFFE), comprising: a power amplifier (PA); and a coupler coupled to an output of the PA; a transmitter, comprising: a driver amplifier (DA) configured to amplify a first radio frequency (RF) signal to generate a second RF signal; and a digital predistortion (DPD) circuit configured to predistort a first baseband signal to generate a second baseband signal, wherein the first RF signal is based on the second baseband signal, and wherein the DPD circuit is configured to predistort the first baseband signal based on a nonlinearity characteristic of the DA based at least in part on a feedback RF signal received from the coupler of the RFFE.

Aspect 2: The transmitter system of aspect 1, wherein: the RFFE further includes a PA bypass switch coupled between an input and an output of the PA; and the coupler is configured to generate the feedback RF signal while the PA bypass switch is closed to bypass the PA.

Aspect 3: The transmitter system of aspect 1, wherein: the PA is configured to amplify a third RF signal to generate a fourth RF signal; and the third RF signal is substantially the same as or based on the second RF signal.

Aspect 4: The transmitter system of aspect 3, wherein the feedback RF signal is based on the fourth RF signal while the PA is operated exclusively in a substantially linear region.

Aspect 5: The transmitter system of aspect 3 or 4, wherein the RFFE further comprises a signal tracking voltage regulator configured to generate a supply voltage for the PA to operate the PA exclusively in a substantially linear region while the coupler generates the feedback RF signal.

Aspect 6: The transmitter system of aspect 5, wherein the signal tracking voltage regulator is configured to generate the supply voltage for the PA based on a characteristic of the third or fourth RF signal.

Aspect 7: The transmitter system of aspect 6, wherein the characteristic comprises an average power of the third or fourth RF signal.

Aspect 8: The transmitter system of aspect 6, wherein the characteristic comprises an envelope of the third or fourth RF signal.

Aspect 9: The transmitter system of any one of aspects 5-8, wherein the transmitter comprises a control circuit configured to generate a control signal to control the signal tracking voltage regulator of the RFFE to generate the supply voltage for the PA.

Aspect 10: The transmitter system of any one of aspects 1-9, wherein the transmitter further comprises a supply voltage generating circuit configured to generate a supply voltage for the DA to cause the DA to operate in a nonlinear region.

Aspect 11: The transmitter system of aspect 10, wherein the transmitter further comprises a control circuit configured to generate a control signal to control the supply voltage generating circuit in generating the supply voltage for the DA.

Aspect 12: The transmitter system of any one of aspects 1-11, wherein the transmitter further comprises a DPD calibration circuit configured to calibrate the DPD based on the feedback RF signal from the RFFE via a feedback path between the RFFE and the transmitter.

Aspect 13: The transmitter system of any one of aspects 1-12, wherein: the transmitter is implemented in a first integrated circuit (IC); and the RFFE is implemented in a second IC.

Aspect 14: The transmitter system of any one of aspects 1-13, wherein: the transmitter is implemented in an integrated circuit (IC); and the RFFE is implemented as a discrete circuit disposed on a printed circuit board.

Aspect 15: The transmitter system of any one of aspects 1-14, wherein the DPD circuit is further configured to predistort the first baseband signal or another baseband signal based on a nonlinearity characteristic of the PA.

Aspect 16: A method of generating a transmit radio frequency (RF) signal in a transmitter system, comprising: amplifying a first radio frequency (RF) signal to generate a second RF signal in accordance with a nonlinear transfer function at a transmitter; receiving a feedback RF signal from an RF front end (RFFE) at the transmitter, wherein the feedback RF signal is based on the transmit RF signal; and predistorting a baseband signal based on the feedback RF signal to achieve a substantially linear amplitude relationship between the transmit RF signal and the baseband signal.

Aspect 17: The method of aspect 16, wherein amplifying the first RF signal to generate a second RF signal is performed by a driver amplifier (DA).

Aspect 18: The method of aspect 17, further comprising biasing the DA to achieve the nonlinear transfer function.

Aspect 19: The method of any one of aspects 16-18, further comprising bypassing a power amplifier (PA) at the RFFE while providing the feedback RF signal to the transmitter.

Aspect 20: The method of any one of aspects 16-18, further comprising amplifying the second RF signal to generate the transmit RF signal with a substantially linear amplitude transfer function by a power amplifier (PA) at the RFFE.

Aspect 21: The method of aspect 20, further comprising providing a supply voltage to the PA, wherein the supply voltage tracks an average power of the second RF signal.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples described herein but is to be accorded the widest scope consistent with the principles and novel features disclosed herein.

What is claimed:

1. A transmitter system, comprising:
a radio frequency front end (RFFE), comprising:
a power amplifier (PA); and
a coupler coupled to an output of the PA;
a transmitter, comprising:
a driver amplifier (DA) configured to amplify a first radio frequency (RF) signal to generate a second RF signal; and
a digital predistortion (DPD) circuit configured to predistort a first baseband signal to generate a second baseband signal, wherein the first RF signal is based on the second baseband signal, and wherein the DPD circuit is configured to predistort the first baseband signal based on a nonlinearity characteristic of the DA based at least in part on a feedback RF signal received from the coupler of the RFFE.

2. The transmitter system of claim 1, wherein:
the RFFE further includes a PA bypass switch coupled between an input and an output of the PA; and
the coupler is configured to generate the feedback RF signal while the PA bypass switch is closed to bypass the PA.

3. The transmitter system of claim 1, wherein:
the PA is configured to amplify a third RF signal to generate a fourth RF signal; and
the third RF signal is substantially the same as or based on the second RF signal.

4. The transmitter system of claim 3, wherein the feedback RF signal is based on the fourth RF signal.

5. The transmitter system of claim 3, wherein the RFFE further comprises a signal tracking voltage regulator configured to generate a supply voltage for the PA to operate the PA exclusively in a substantially linear region while the coupler generates the feedback RF signal.

6. The transmitter system of claim 5, wherein the signal tracking voltage regulator is configured to generate the supply voltage for the PA based on a characteristic of the third or fourth RF signal.

7. The transmitter system of claim 6, wherein the characteristic comprises an average power of the third or fourth RF signal.

8. The transmitter system of claim 5, wherein the transmitter comprises a control circuit configured to generate a control signal to control the signal tracking voltage regulator of the RFFE to generate the supply voltage for the PA.

9. The transmitter system of claim 1, wherein the transmitter further comprises a supply voltage generating circuit configured to generate a supply voltage for the DA to cause the DA to operate in a nonlinear region.

10. The transmitter system of claim 9, wherein the transmitter further comprises a control circuit configured to generate a control signal to control the supply voltage generating circuit in generating the supply voltage for the DA.

11. The transmitter system of claim 1, wherein the DPD circuit is further configured to predistort the first baseband signal or another baseband signal based on a nonlinearity characteristic of the PA.

12. The transmitter system of claim 1, wherein the transmitter further comprises a DPD calibration circuit configured to calibrate the DPD circuit based on the feedback RF signal from the RFFE via a feedback path between the RFFE and the transmitter.

13. The transmitter system of claim 1, wherein:
the transmitter is implemented in a first integrated circuit (IC); and
the RFFE is implemented in a second IC.

14. The transmitter system of claim 1, wherein:
the transmitter is implemented in an integrated circuit (IC); and
the RFFE is implemented as a discrete circuit disposed on a printed circuit board.

15. A method of generating a transmit radio frequency (RF) signal in a transmitter system, comprising:
amplifying a first radio frequency (RF) signal to generate a second RF signal in accordance with a nonlinear transfer function at a transmitter;
receiving a feedback RF signal from an RF front end (RFFE) at the transmitter, wherein the feedback RF signal is based on the transmit RF signal; and
predistorting a baseband signal based on the feedback RF signal to achieve a substantially linear amplitude relationship between the transmit RF signal and the baseband signal.

16. The method of claim 15, wherein amplifying the first RF signal to generate a second RF signal is performed by a driver amplifier (DA).

17. The method of claim 16, further comprising biasing the DA to achieve the nonlinear transfer function.

18. The method of claim 15, further comprising bypassing a power amplifier (PA) at the RFFE while providing the feedback RF signal to the transmitter.

19. The method of claim 15, further comprising amplifying the second RF signal to generate the transmit RF signal with a substantially linear amplitude transfer function by a power amplifier (PA) at the RFFE.

20. The method of claim 19, further comprising providing a supply voltage to the PA, wherein the supply voltage tracks an average power of the second RF signal.
